(19) United States
(12) Patent Application Publication
(10) Pub. No.: US 2006/0175530 A1
(43) Pub. Date: Aug. 10, 2006

(54) Sub-pixel resolution and wavefront analyzer system

(76) Inventors: Michael John Wilcox, Colorado Springs, CO (US); Donald Claude Thelen JR., Bozeman, MT (US)

Correspondence Address: LAW OFFICE OF DALE B. HALLING, LLC, 655 SOUTHPOINTE COURT, SUITE 100, COLORADO SPRINGS, CO, 80906, US

(21) Appl. No.: 11/051,850

(22) Filed: Feb. 4, 2005

(51) Int. Cl. H01L 27/00

(52) U.S. Cl. 250/208.1

(57) ABSTRACT

A sub-pixel resolution system that overcomes these and other problems has a number of optical sensors. Each of the optical sensors has a field of view that overlaps a neighboring optical sensors field of view. A number of contrast enhancement circuits are coupled between each of the optical sensors. An induced current circuit is coupled to a group of the optical sensors.

### RELATED APPLICATIONS

None.

### FIELD OF THE INVENTION

The present invention relates generally to the field of optical sensors and more particularly to a method for extracting sub-pixel resolution in real-time and a wavefront sensor for an adaptive optics system.

### BACKGROUND OF THE INVENTION

Optical tracking systems face two major challenges. The first challenge is that each pixel has a finite field of view and sensitivity is uniform across its surface. This results in the photosensing element being unable to determine the location of an object or a feature in an image that is smaller than a single pixel. A number of solutions have been tried to overcome this limitation. One solution is to purposely blur the image over multiple pixels and calculate the centroid of the blurred image. This solution has had limited success, but requires computation and serial sampling and, therefore, is no longer in real-time. The approach also functions at the price of blurring any other objects in the field of view. Another approach is to optically magnify the image until the feature is larger than a single pixel. However, this produces the same problem of expanding the image, changing the contrast ratio and also narrows the entire field of view of the pixel array by the optical magnification factor of the image. The importance of blurring or magnifying a feature in an image is that the light flux (photons per square centimeter per second, which is what you are trying to detect) is drastically reduced (2 times the change in image size yields the square root of the photon flux; 3 times, the cube root, 4 times, the fourth root and so on) and compromises the ability of the detector array to resolve the change in luminance. As Bucklew and Saleh showed in 1985, resolution is a matter of contrast sensitivity. Therefore, degrading the contrast sensitivity compromises system detection ability. Another problem is that most image devices accumulate charge and then digitize the magnitude of this stored charge. The charge is periodically sampled and then drained to start a new charge accumulation period. This process is inherently limited to a relatively slow update rate compared to the speed of analog electronic signals. Thus this accumulate, digitize and drain process is a rate limiting process. The sampling process or the readout rate of a sensor array and transfer to a computer's memory space constitutes a large delay in subsequent processing. Furthermore, if an image moves across multiple pixels during an update cycle, it is hard to distinguish this from a large image or to determine the track of the image. There have been attempts to only perform this accumulate, digitize and drain process for the pixels near the image of interest in order to speed up these image systems. Unfortunately, this process is still relatively slow and blinds the other parts of the imaging system. In fast sensor systems with few pixels, sampling is still required, the rate limiting step here is transfer of the time sample to a memory space in a computer so that the information from the sensors can be manipulated by the computer's central processor. Still other systems have been used to extract subpixel resolution by calculating the centroid of an object at different time points and then computing the displacement distance with higher accuracy than a single pixel dimension or the pixel spacing.

Other approaches to subpixel resolution involve first identifying the edge of an object then calculating the position of the center of mass of that object at subsequent time points. Alternatively, wavelet encoding an edge from the partial values in adjacent pixels can be used to infer the position of an edge of an object. Then recomputing that position at subsequent time points can be used to locate a moving edge with higher resolution than the pixel spacing. However, both these approaches require computation and, therefore, no longer operate in real-time.

Thus there exists a need for a sub-pixel resolution system that operates without blurring or magnifying the image and has a much faster update rate than present imaging systems.

### SUMMARY OF THE INVENTION

A sub-pixel resolution system that overcomes present sensor shortfalls and other problems has a number of optical sensors. Each of the optical sensors has a field of view that overlaps a neighboring optical sensor's field of view. A number of contrast enhancement circuits are coupled between each of the optical sensors. An induced current circuit is coupled to a group of the optical sensors. Each of the optical sensors may be real time current generators and have a Gaussian far field sensitivity. The Gaussian far field sensitivity may be created by a ball lens optically coupled to each of the optical sensors. Alternatively the Gaussian far field sensitivity may be created by employing a thin mask deposited at the edge of each sensor or by electrically coupling the bases of bipolar transistors of the photosensors in a single cartridge together or by using electronic weighting approaches. In one embodiment, a sub-pixel resolution system has a number of optical sensors. Each sensor has Gaussian or other linear or nonlinear far-field angular sensitivity. A number of contrast enhancement circuits are coupled between the optical sensors. An induced current circuit is coupled to a group of the optical sensors. The optical sensors may have a field of view that overlaps a neighboring optical sensors field of view. An optical filter may cover one of the optical sensors. The optical sensors may form two or more cartridges and have an output of a first cartridge coupled to a first input of a comparator and an output of a second cartridge coupled a second input of the comparator. A digital processor may be coupled to an output of the optical sensors. The digital processor may be coupled to an output of the comparator. The advantage of such a circuit is that local processing increases speed using a parallel approach while a cooperative process between cartridges helps detect features that are larger than the field of view of a single cartridge. All this processing is accomplished without first requiring a global sampling process and moving that data to a memory space for a central processor to manipulate.

In one embodiment, a wavefront analyzer system has a sub-pixel analog resolution system. A wavefront analyzer has an input coupled to an output of the analog sub-pixel resolution system. The analog sub-pixel resolution system may have a number of optical sensors. The field of view an optical sensor may overlap a neighboring optical sensors field of view. The sensors may have Gaussian far field sensitivity. The Gaussian far field sensitivity may be created by a ball lens in an optical path between the deformable mirror and the optical sensors. The sub-pixel resolution system may have a number of contrast enhancement circuits. Each of the contrast enhancement circuits is coupled between two the optical sensors. An induced current circuit is coupled to a group of the optical sensors. The optical sensors form at least two cartridges and an output of a first cartridge is compared with an output of a second cartridge.

### BRIEF DESCRIPTION OF THE DRAWINGS

FIG. 1 is an electrical schematic diagram of a sub-pixel resolution system in accordance with one embodiment of the invention;

FIG. 2A is a three dimensional diagram of the far field Gaussian sensitivity of the optical sensors in accordance with one embodiment of the invention;

FIG. 2B is a two dimensional diagram of the overlapping field of views of optical sensors in accordance with one embodiment of the invention;

FIG. 3A is a cross sectional view of the optical sensors and associated optics in accordance with one embodiment of the invention;

FIG. 3B is a cross sectional view of a single ball lens and optical fiber in accordance with one embodiment of the invention;

FIG. 4A is a dimension diagram of three cartridges of optical sensors and the associated comparator circuitry in accordance with one embodiment of the invention;

FIG. 4B is a two dimensional diagram of a comparator element called L4. The circle represents the photodetector input field of view of a single cartridge. The limbs labeled a, b, and c or bidirectional inputs and outputs to neighboring L4 elements, used to compare inputs from their parent cartridges in order to segment objects in an image.

FIG. 4C shows a network of seven cartridges of optical sensors and the associated L4 comparator circuitry in accordance with one embodiment of the invention;

FIG. 5 is a block diagram of a sub-pixel resolution system and digital processing array in accordance with one embodiment of the invention; and

FIG. 6 is an adaptive optics system in accordance with one embodiment of the invention.

### DETAILED DESCRIPTION OF THE DRAWINGS

The present invention describes a sub-pixel resolution system that uses an array of analog optical detectors with overlapping fields of view to obtain sub-pixel resolution. The optical detectors are coupled to analog processing circuits that enhance contrast between optical detectors and induce current to detect low light images. Because the processing is performed using analog circuits and the optical detectors are analog circuits, the system is essentially a real time resolution system. Some applications may require digitizing of outputs and post processing that may slow down the resolution system, but all the initial detection and processing is essentially real time.

For a vision system, objects in an image consist of features of low and high spatial frequency. High spatial frequencies down to the diffraction limit (2 times the wavelength of light being imaged) are smaller that the physical size of an individual pixel. The invention provides improved tracking of targets with high accuracy and resolving small features, smaller than the size of the optical detector, the picture element or pixel.

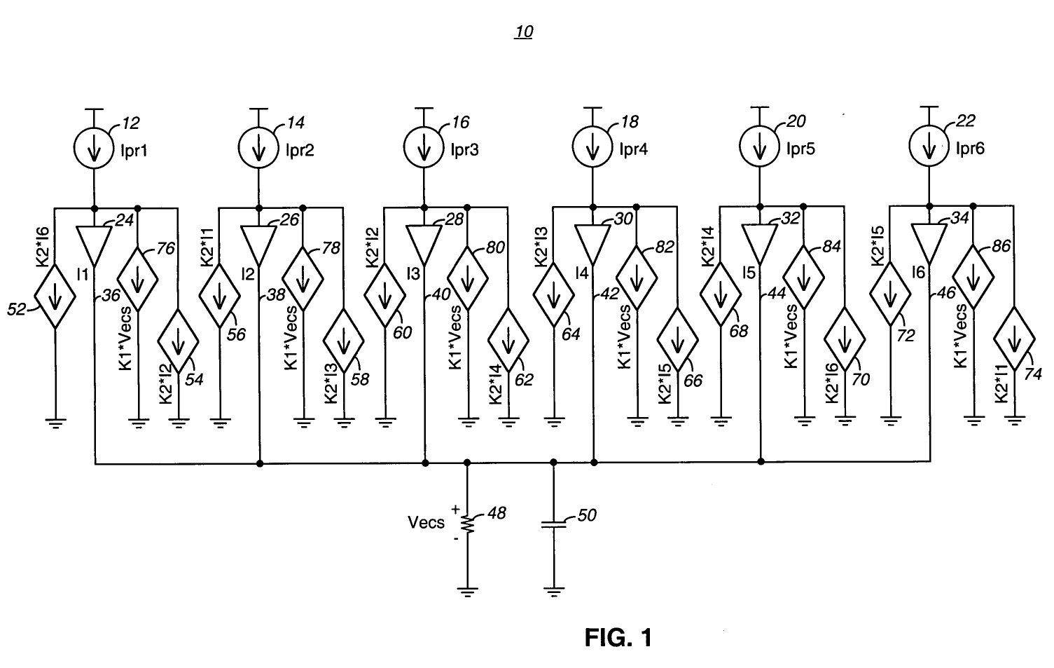

FIG. 1 is an electrical schematic diagram of a sub-pixel resolution system 10 in accordance with one embodiment of the invention. The system 10 has six optical sensors 12, 14,16, 18, 20, 22 that are modeled as current sources. The current sources 12, 14, 16, 18, 20, 22 are coupled to amplifiers 24, 26, 28, 30, 32, 34. All the outputs 36, 38, 40, 42, 44, 46 of the amplifiers 24, 26, 28, 30, 32, 34 are coupled to a cartridge resistor 48 and cartridge capacitor 50 that generate a voltage (Vecs). This voltage provides a reference for the activity within the cartridge. A programmable variable (K1) multiplied by Vecs controls a current mirror or voltage dependent current source (diamond symbol with arrow, 76, 78, 80, 82, 84, 86 in FIG. 1) that provides contrast enhancement by pulling current away from the input nodes of amplifiers 24, 26, 28, 30, 32, 34, when K1 has a negative value. That contrast enhancement is based on activity among the contributing sensors 12,14, 16, 18, 20, 22. If K1 has a positive value, then any activity from any of the sensors 12, 14, 16, 18, 20, 22 will be augmented and amplified by the value of K1 and injected into the processing circuitry, essentially multiplying the input from any of the sensors in the cartridge. This action provides enhanced sensitivity of the sensors at low illumination levels. For each of the optical detectors 12, 14, 16, 18, 20, 22 there is a separate contrast enhancement circuit involving only the immediate neighboring sensor rather than the pooled sensors as the Vecs circuit does. The contrast enhancement circuit for the first optical detector 12 has a first current source 52 and a second current source 54. The first current source 52 generates a current that is equivalent to the output current 46 (I6) times a constant K2. The second current source 54 generates a current that is equivalent to the output current 38 (I2) times a constant K2. Note that these two current sources 52, 54 are a function of the neighboring optical detectors 14, 22 output currents 38, 46. By selecting the correct value for K2 we can cause the output current (I1) 36 to be decreased when a current is sensed at the neighboring optical detector 14. This increases the difference in the two currents 36, 38 which increases the contrast between the two detectors. This is not a winner-take-all (as in a current shunting or inhibitory circuit, although it could be) but rather a proportional contrast sensor.

The second optical detector 14 has a first current source 56 and a second current source 58. The first current source 56 generates a current that is equivalent to the output current 36 (I1) times a constant K2. The second current source 58 generates a current that is equivalent to the output current 40 (I3) times a constant K2. The third optical detector 16 has a first current source 60 and a second current source 62. The first current source 60 generates a current that is equivalent to the output current 38 (I2) times a constant K2. The second current source 62 generates a current that is equivalent to the output current 42 (I4) times a constant K2. The fourth optical detector 18 has a first current source 64 and a second current source 66. The first current source 64 generates a current that is equivalent to the output current 40 (I3) times a constant K2. The second current source 66 generates a current that is equivalent to the output current 44 (I5) times a constant K2. The fifth optical detector 20 has a first current source 68 and a second current source 70. The first current source 68 generates a current that is equivalent to the output current 42 (I4) times a constant K2. The second current source 70 generates a current that is equivalent to the output current 46 (I6) times a constant K2. The sixth optical detector 22 has a first current source 72 and a second current source 74. The first current source 72 generates a current that is equivalent to the output current 44 (I5) times a constant K2. The second current source 74 generates a current that is equivalent to the output current 36 (I1) times a constant K2.

Each of the optical detectors 12, 14, 16, 18, 20, 22 also has an induced current circuit 76, 78, 80, 82, 84, 86. The induced current circuits 76, 78, 80, 82, 84, 86 are current sources that are a product of the constant K1 and the voltage (Vecs) across the cartridge resistor 48. By setting the value of K1 correctly the cartridge of optical detectors is able to sense the presence of light that might not be sensed by any of the individual optical detectors 12, 14, 16, 18, 20, 22. Note that the output from each detector is of interest as well as the cartridge output.

The advantage of two sources of contrast enhancement based on either overall activity within the cartridge or activity in the nearest neighbors allows different levels of contrast enhancement and helps in subsequent post-processing used to identify features detected within a given cartridge and to share that information with neighboring cartridges. The values of K1 and K2 can be programmed in or adaptive circuitry can be used to determine the values and used to extract camouflaged features of objects with low contrast. Voltage gain and offset can be applied to the current mirrors or to the operational amplifiers to control the working range and dynamic range of the detectors. These variables (K1, K2 offset and gain) can be controlled by adaptive circuitry that allows well-camouflaged objects to be extracted from the background.

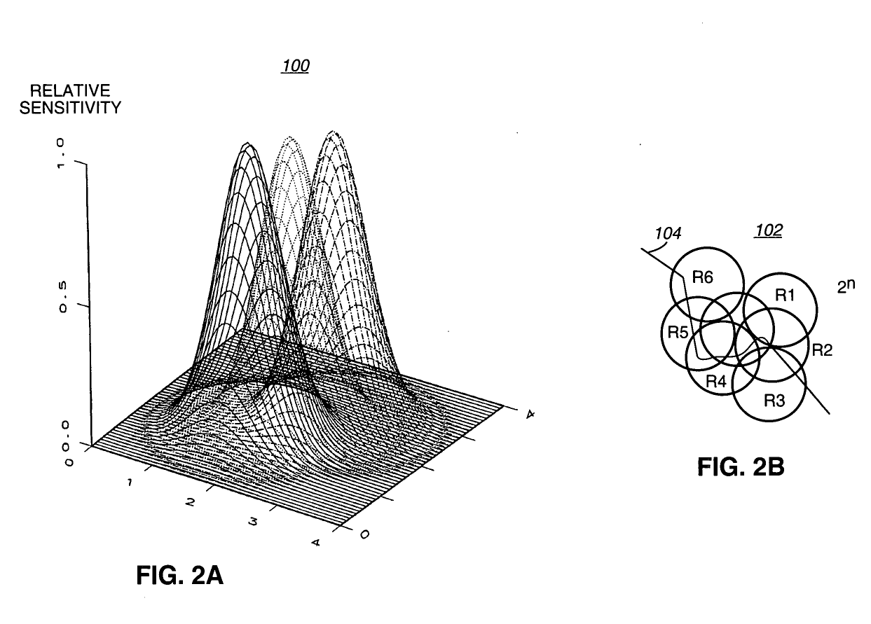

FIG. 2A is a three dimensional diagram of the far field sensitivity 100 of three optical sensors in accordance with one embodiment of the invention. This three dimensional graph shows the overlap of far field sensitivity of three of the seven optical detectors in a cartridge, each having a Gaussian or other nonlinear sensitivity profile. The optical detectors have 50% overlap. It has been shown mathematically that there is no spatial resolution limit between two adjacent detectors, if the contrast ratio of the object being detected is high enough. However, there are contrast ratio limitations that can affect the ability to detect the spatial resolution. The advantage of using a Gaussian or other continuous function is that the position of an object within the detector's field of view can be sensed with higher resolution than either the detector's physical width or the spacing between detectors. Overlapping the optical sensors' fields of view allows for sub-pixel resolution. FIG. 2B is a two dimensional diagram 102 of the overlapping field of views of optical sensors in accordance with one embodiment of the invention. The circles show where the far field sensitivity is 50% of the peak sensitivity for a cartridge of seven optical detectors in a close packed hexagonal arrangement. A trace 104 represents the path of a point source across the detectors. The overlapping arrangement allows for 2ⁿ zero crossing, where n is the number of pixels or detectors. So in this case there are 128 zero crossing in this optical detector arrangement. Zero crossings are often used to determine the path of a point source. The more zero crossing the better able the image system is able to determine the path of an object. Standard CCD (Charge Coupled Devices) do not have pixels with overlapping fields of view. As a result, number of zero crossings is n+1. As a result, the overlapping fields of view significantly improve the performance of the present sub-pixel resolution system over previous resolution systems.

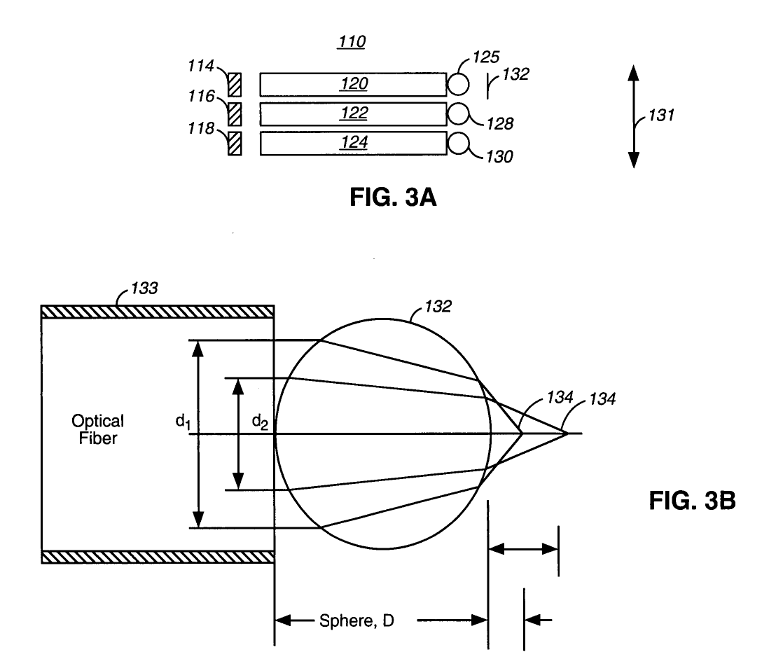

FIG. 3A is a cross sectional view of the optical sensors and associated optics 110 in accordance with one embodiment of the invention. Three optical detectors 114, 116, 118 are optically coupled through fiber optical cables 120, 122, 124 to three ball lenses 126, 128, 130. The ball lens 126 in combination with the optical fiber 120, inherently produces an overlapping field of view among the optical detectors 114, 116, 118. Note that optical system has an imaging lens system 131 in front of the ball lenses 126, 128, 130. In addition, the ball lenses 126, 128, 130 result in an essentially Gaussian far field intensity. A filter 132 is shown in front of one of the ball lenses 126. In one embodiment, the optical detectors are photo-transistors that have a very broad spectral range. Filters can be used to select for particular wavelengths of interest. Note that another method of obtaining a Gaussian like far field sensitivity pattern is to have relatively small photodiodes, for instance photodiodes that are less than about five microns. The reason for this is that the edge of the photodiode is more sensitive than the center. In addition, the conductive traces may be placed over the optical sensors and has a masking effect that contributes to a Gaussian like far field sensitivity. In one embodiment, the ball lenses are placed on the optical sensors. The imaging lens may be a facet lens from a compound eye or a regular lens from a camera.

FIG. 3B is a cross sectional view of a single ball lens 132 and optical fiber 133 in accordance with one embodiment of the invention. The image 134 is focused in front of the ball lens 132. When the image is moved up or down the result is that some of the light falls outside the optical fiber 133 and onto an adjacent fiber.

The overlapping fields of view may be created by having thin traces or masks between the optical sensors which will diffuse the light between the two adjacent sensors. The traces are commonly thinner (Z-axis or deposition layer thickness) than the diffraction limit of the light being imaged, so they do not impair light transmission but allow diffusion of light into the neighboring photosensor. Alternatively a modified sensor with the bases of the bipolar transistors connected to each other or an electronic weighting approach may be used to create a position dependent output for the sensor. In another embodiment, the doping of the sensor may be non-uniform and this will result in a position dependent photosensitivity for the sensor. The ball lens, coupled sensors, mask or trace (141 of FIG. 3) and non-uniform doping are all image position systems.

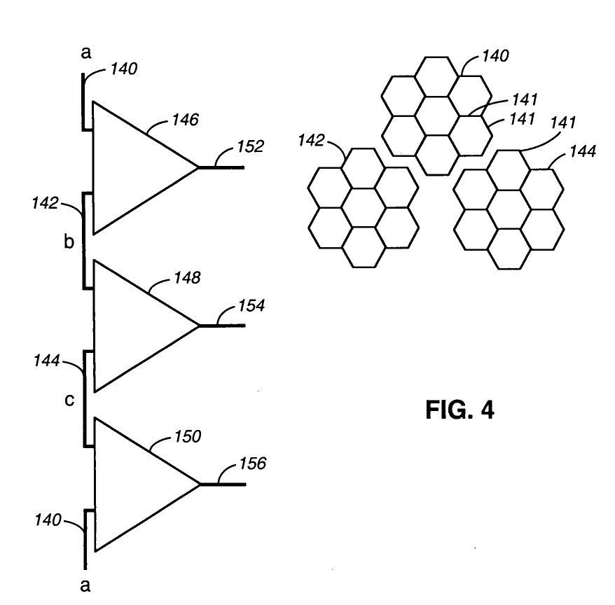

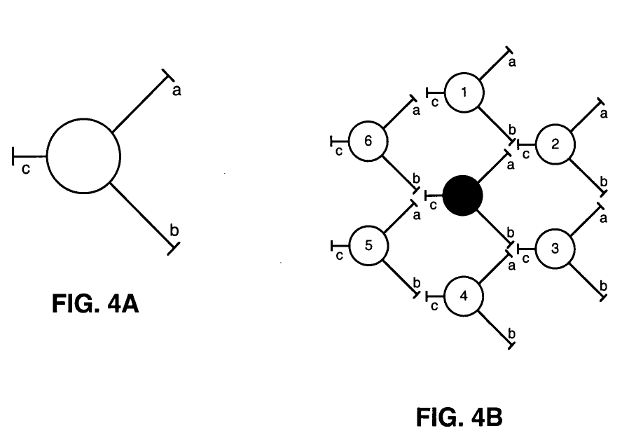

FIGS. 4a & b are a diagrams of an element (called L4) that connects adjacent cartridges. The circle represents seven photoreceptor inputs of a single cartridge. The limbs a, b, and c represent inputs and outputs to and from neighboring L4 elements. The output of each cartridge is compared by L4 providing local information processing within its own cartridge field of view and provides redundancy to the network of optical sensors 140, 142, 144, 146, 148, 150 and the associated comparator circuitry in accordance with one embodiment of the invention. FIG. 4b shows a network of seven L4 elements. Such a network provides a cooperative approach using comparators to extract coherent information abut an object in an image that is larger than a single cartridge. Thus, a local process is used to isolate or segment an object with arbitrary geometry from background in an image. In one embodiment of the invention, cartridges 140, 142, 144, 146, 148, 150 have seven optical detectors each in a hexagonal close packed structure. The output of the cartridges 140, 142, 144, 146, 148, 150 which is the voltage Vecs shown in FIG. 1, is coupled into the comparators 152, 154, 156. The outputs 158, 160, 162 of the comparators 152, 154, 156 are used to share information across the cartridges. For instance, the comparators 152, 154, 156 can be used to determine if an edge extends across a multiple of the cartridges or is located only on a single cartridge. In the network, each L4 compares its own cartridge input to the outputs of adjacent L4 elements. Information processing is local, within each cartridge. The output of each cartridge is compared to the outputs of each of its 2, 4, 6, or 8 neighbors, depending on the packing arrangement of the photodetectors. There is no leakage of current through resistors as Langan and others have done. There is no output current coupling cartridges, as this would eliminate the subpixel resolution information contained in each cartridge. Using a comparator, all ideal resistances are high enough that any one output does not alter a neighbor's processing.

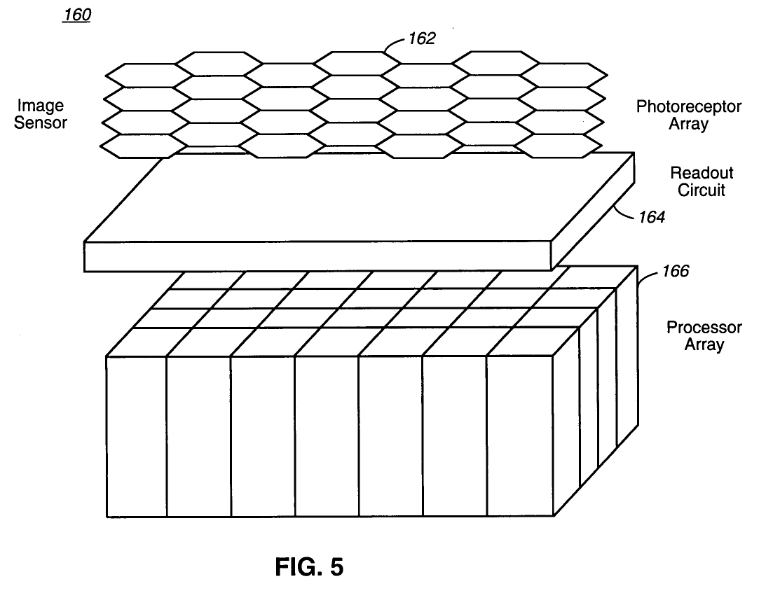

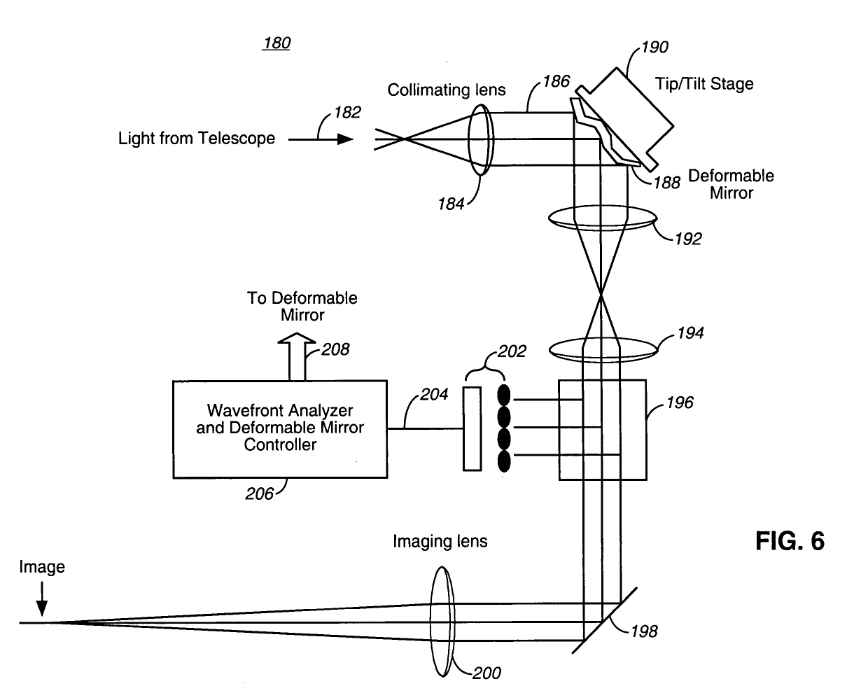

FIG. 5 is a block diagram of a sub-pixel resolution system and digital processing array 160 in accordance with one embodiment of the invention. The system 160 has an array of analog optical detectors or pixels 162 in a hexagonal close packed structure. The optical sensors 162 have overlapping fields of view as described above. Below the optical sensors 162 is the analog readout and processing circuit 164, such as the circuits shown in FIG. 1 and FIG. 4. The readout circuitry 164 is coupled to a processor or processor array 166. The processor array converts the analog output signals into information that can be used by a larger system such as the system in FIG. 6.

FIG. 6 is an adaptive optics system 180 in accordance with one embodiment of the invention. The system 180 receives light from a telescope 182 into a collimating lens 184. The collimated light 186 impinges upon a deformable mirror 188. The deformable mirror 188 is mounted on a tip/tilt stage 190. The light then passes through a pair of lenses 192, 194 and is collimated again. A beam splitter 196 transfers part of the light to a mirror 198 and an imaging lens 200 and part of the light to a sub-pixel resolution system 202, such as that described above. The output 204 of the sub-pixel resolution system 202 is coupled to a wavefront analyzer and deformable mirror controller 206. The analyzer determines the shape of the wavefront and the controller has an output 208 that directs the deformable mirror to adjust the surface of the deformable mirror to remove any aberrations, such as those caused by atmospheric conditions. Since the sub-pixel resolution system 202 has analog optical detector and analog front end processing, the system 180 is able to adjust more quickly for changes in the wavefront. This allows this system to significantly reduce the time necessary to form an image of a faint star, since the wavefront is continuously being update. For faint stars this can reduce the exposure time in half or less. This makes the telescope system twice as productive as present adaptive optics systems.

The tip-tilt stage removes low order aberration and the deformable mirror actuators correct the high order aberration as in an adaptive optics system using a Shack-Hartmann wavefront sensor. Our fly-eye sensor replaces the Shack-Hartmann wavefront sensor and operates in real-time without requiring a CCD to sense the optical signal from different parts of the beam. The advantage in this application is that the fly-eye sensor provides much higher resolution and operates in real-time without sampling the photodetector array. In addition to the computational savings of not having to sample and move data to access a central processor, no numerical computation is required, as it is using a CCD array.

Thus there has been described a high resolution system that has sub-pixel resolution without blurring the image or magnifying the image and has a much faster update rate than present resolution systems. Note that while the description has focused on detecting electromagnetic energy, the system may be used for sound energy, radio waves, infrared waves, particles or other types of energy.

While the invention has been described in conjunction with specific embodiments thereof, it is evident that many alterations, modifications, and variations will be apparent to those skilled in the art in light of the foregoing description. Accordingly, it is intended to embrace all such alterations, modifications, and variations in the appended claims.

What is claimed is:

1. A sub-pixel resolution system, comprising:
a plurality of optical sensors each of the plurality of optical sensors having a field of view that overlaps a neighboring optical sensor's field of view;
a plurality of contrast enhancement circuits, each of the contrast enhancement circuits coupled between two of the plurality of optical sensors; and
an induced current circuit coupled to a group of the plurality of optical sensors.

2. The system of claim 1, wherein each of the plurality of optical sensors are real time current generators.

3. The system of claim 1, wherein each of the plurality of optical sensors has a Gaussian far field sensitivity.

4. The system of claim 3, wherein the Gaussian far field sensitivity is created by a ball lens optically coupled to each of the plurality of optical sensors.

5. The system of claim 3, wherein the Gaussian far field sensitivity is created by having a trace between each of the plurality of optical sensors.

6. The system of claim 1, wherein the plurality of optical sensors form at least two cartridges and an output of a first cartridge is compared with an output of a second cartridge.

7. The system of claim 1, wherein each of the contrast enhancement circuits is an analog circuit.

8. A sub-pixel resolution system, comprising:
a sensor; and
an image position system coupled to the sensor that adjusts an output of the sensor based on a position of an image on the sensor.

9. The system of claim 8, wherein the image position system is a ball lens.

10. The system of claim 8, wherein the image position system is a mask along an edge of the sensor.

11. The system of claim 9, further including a plurality of optical sensors forming at least two cartridges and an output of a first cartridge is coupled to a first input of a comparator and an output of a second cartridge is to a second input of the comparator.

12. The system of claim 11, further including a digital processor coupled to an output of at least one of the plurality of optical sensors.

13. The system of claim 12, wherein the digital processor is coupled to an output of the comparator.

14. A wavefront analyzer system, comprising:
a analog sub-pixel resolution system; and
a wavefront analyzer, having an input coupled to an output of the sub-pixel analog resolution system

15. The system of claim 14, further including a deformable mirror or micro electromechanical system (MEMS) optically coupled to the sub-pixel analog resolution system and having an input coupled to an output of the wavefront analyzer.

16. The system of claim 15, wherein the sub-pixel analog resolution system has a plurality of optical sensors each having a field of view that overlaps a neighboring optical sensors field of view.

17. The system of claim 16, wherein each of the plurality of sensors has a Gaussian far field sensitivity.

18. The system of claim 17, wherein the Gaussian far field sensitivity is created by a ball lens in an optical path between the deformable mirror and the plurality of optical sensors.

19. The system of claim 18, wherein the sub-pixel resolution system further includes:
a plurality of contrast enhancement circuits, each of the contrast enhancement circuits coupled between two of the plurality of optical sensors; and
an induced current circuit coupled to a group of the plurality of optical sensors.

20. The system of claim 19, wherein the plurality of optical sensors form at least two cartridges and an output of a first cartridge is compared with an output of a second cartridge.
